(19) United States
(12) Patent Application Publication
(10) Pub. No.: US 2022/0322580 A1
(43) Pub. Date: Oct. 6, 2022

(54) SYSTEM AND METHOD FOR UTILIZING GEOTHERMAL COOLING FOR OPERATIONS OF A DATA CENTER

(71) Applicant: Wyoming Hyperscale White Box LLC, Houston, TX (US)

(72) Inventor: Trenton Thornock, Houston, TX (US)

(21) Appl. No.: 17/714,072

(22) Filed: Apr. 5, 2022

Related U.S. Application Data
(60) Provisional application No. 63/170,834, filed on Apr. 5, 2021.

(51) Int. Cl. H05K 7/20; F24T 10/10

(52) U.S. Cl. CPC H05K 7/20781; H05K 7/20272; H05K 7/20263; H05K 7/20236; F24T 10/10

(57) ABSTRACT

Systems and methods using geothermal cooling for data centers include a geothermal cooling loop, at least one heat exchanger, and a data center. The data center comprises one or more server racks in thermal communication with a heat transfer fluid. The at least one heat exchanger is configured to transfer heat from the heat transfer fluid to a geothermal fluid received from a geothermal cooling loop. The geothermal cooling loop comprises at least one supply well penetrating an aquifer, wherein the geothermal fluid is introduced into the aquifer via the at least one supply well. The geothermal cooling loop further comprises at least one return well penetrating at least a second portion of the aquifer and operable to produce at least a portion of the geothermal fluid from the aquifer.

### CROSS-REFERENCE TO RELATED APPLICATIONS

This application claims priority from U.S. Provisional Application Ser. No. 63/170,834 entitled “A data center configuration for saving most of the power consumption by cooling storage drives, network equipment, computing, servers and power provisioning equipment,” filed on Apr. 5, 2021, the entirety of which is incorporated herein by reference.

### BACKGROUND

The present disclosure relates generally to geothermal cooling and, more particularly, to systems and methods for utilizing geothermal cooling for operations of a data center.

Approximately 43% of a data center's operating cost is cooling. The power consumption and the waste heat produced by data center operations may contribute to global warming. Air cooling is currently the predominate cooling method. However, while air cooling (e.g., adiabatic cooling) has reduced data center water consumption, it has not reduced waste heat rejection to the atmosphere. Additionally, air cooling may be highly power inefficient. Changing the cooling medium inside the data center may improve efficiency, but the heat is still expelled to the atmosphere. There is a need to prevent waste heat from data center operations from entering the atmosphere.

### BRIEF DESCRIPTION OF THE DRAWINGS

The following figures are included to illustrate certain aspects of the present disclosure and should not be viewed as exclusive embodiments. The subject matter disclosed is capable of considerable modifications alterations combinations, and equivalents in form and function, without departing from the scope of this disclosure.

FIG. 1 is a schematic diagram of an exemplary geothermal system, according to one or more aspects of the present disclosure.

FIG. 2 is a partial isometric view of an example data center, according to one or more aspects of the present disclosure.

FIG. 3 is a flowchart illustrating an example method using the system of FIG. 1, according to one or more aspects of the present disclosure.

### DETAILED DESCRIPTION

Illustrative embodiments of the present invention are described in detail herein. In the interest of clarity, not all features of an actual implementation may be described in this specification. It will of course be appreciated that in the development of any such actual embodiment, numerous implementation-specific decisions may be made to achieve the specific implementation goals, which may vary from one implementation to another. Moreover, it will be appreciated that such a development effort might be complex and time consuming but would nevertheless be a routine undertaking for those of ordinary skill in the art having the benefit of the present disclosure.

Throughout this disclosure, a reference numeral followed by an alphabetical character refers to a specific instance of an element and the reference numeral alone refers to the element generically or collectively. Thus, as an example (not shown in the drawings), widget “la” refers to an instance of a widget class, which may be referred to collectively as widgets “1” and any one of which may be referred to generically as a widget “1”. In the figures and the description, like numerals are intended to represent like elements.

The terms “couple” or “couples,” as used herein, are intended to mean either an indirect or direct connection. Thus, if a first device couples to a second device, that connection may be through a direct connection, or through an indirect electrical connection or a shaft coupling via other devices and connections.

To facilitate a better understanding of the present disclosure, the following examples of certain embodiments are given. In no way should the following examples be read to limit, or define, the scope of the disclosure. Embodiments described below with respect to one implementation are not intended to be limiting.

The present disclosure provides for systems and methods for utilizing geothermal cooling for operations of a data center. The disclosed systems and methods may, in certain embodiments, prevent data center waste heat from entering the atmosphere by sequestering the waste heat in the rock that comprises the earth's crust. In embodiments, a closed loop system may employ water or a water and glycol mixture to step-down the temperature of a working fluid to an acceptable temperature for optimum operating efficiency. In some embodiments, the methods or systems of the present disclosure may prevent a substantial portion (e.g., 80%, 85%, 90%, 95%, or higher) of the waste heat generated by data centers from being rejected to the atmosphere.

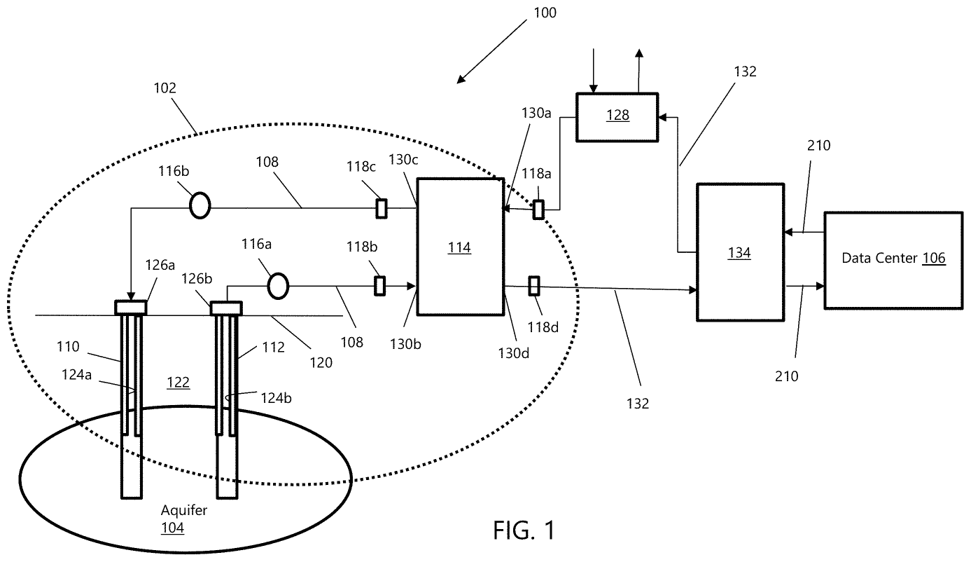

FIG. 1 is a schematic diagram of an exemplary geothermal system 100 that may employ the principles of the present disclosure, according to one or more embodiments. As illustrated, the geothermal system 100 may include a geothermal cooling loop 102, an aquifer 104, and a data center 106. The geothermal cooling loop 102 may be a control loop utilized to regulate a parameter to a desired value. In embodiments, the geothermal cooling loop 102 may be a closed loop system or an open loop system. With reference to FIG. 1, the geothermal cooling loop 102 may be illustrated as an open loop system, but one of ordinary skill in the art will recognize that the geothermal cooling loop 102 may be modified to function as a closed loop system. In any event, the geothermal and data system as a whole may be a closed loop, in that no waste heat is rejected to the atmosphere, but rather is rejected into the earth. The geothermal cooling loop 102 may be operable to cycle a geothermal fluid 108 between the aquifer 104 and a heat exchanger 114 to facilitate heat transfer between the geothermal fluid 108 and a fluid circulating about the data center 106 (for example, the heat transfer fluid 210 further described below). Without limitations, the geothermal fluid 108 may comprise water or water and glycol. In some embodiments, the water of the geothermal fluid 108 may be groundwater from the aquifer 104, water supplied from an external source, or any combination thereof.

In embodiments, there may be one or more intermediary steps of heat transfer between the geothermal cooling loop 102 and the data center 106. As illustrated, there may be an intermediate fluid 132 circulating between the geothermal cooling loop 102 and the data center 106 operable to transfer heat between the geothermal fluid 108 and the heat transfer fluid 210. Geothermal system 100 may be illustrated comprising one intermediate control loop system (for example, the intermediate fluid 132), but one of ordinary skill in the art will recognize that the geothermal system 100 may be modified to function with any number of intermediary control loop systems facilitating heat transfer. Without limitations, the intermediate fluid 132 may comprise water, water and glycol, or any suitable fluid for transferring heat between the data center and the geothermal cooling loop 102. A person of skill in the art, with the benefit of this disclosure, would understand compositions of the intermediate fluid that would be suitable for certain embodiments of the present disclosure.

For example, the data center 106 may produce waste heat as a result of operations. In certain embodiments, heat may be generated by electronic and computer systems, such as servers, data racks, and other computing devices. Typically, the waste heat is rejected to the atmosphere (e.g., through adiabatic cooling) and may be harmful to the environment. With reference to the present disclosure, the waste heat may be transferred to the geothermal cooling loop 102 for transfer into the earth's crust through the aquifer 104. Without wishing to be limited by theory, the earth and the aquifer 104 are used as a heat sink to absorb some of the waste heat generated by the data center 106.

As illustrated, the geothermal cooling loop 102 may comprise a supply well 110, a return well 112, the heat exchanger 114, one or more system pumps 116, and one or more temperature sensors 118. The supply well 110 may extend from a ground surface 120 through one or more subterranean formations 122 and penetrate at least a portion of the aquifer 104. The supply well 110 may be operable to receive the geothermal fluid 108 and introduce the geothermal fluid 108 into the aquifer 104. Similarly, the return well 112 may extend from the ground surface 120 through one or more subterranean formations 122 and penetrate at least a portion of the aquifer 104. In embodiments, the return well 112 may penetrate at least a separate portion of the aquifer in relation to the supply well 110. For example, the supply well 110 may be disposed a certain distance away from the return well 112 penetrating a first portion of the aquifer, wherein the return well 112 may penetrate a second portion of the aquifer 104. Without limitations, the distance between the supply well 110 and the return well 112 may be selected from a range of from about 0.5 miles to about 5 miles. The return well 112 may be operable to produce at least a portion of the geothermal fluid 108 from the aquifer 104. Although shown as vertical wells, in one or more embodiments, the supply well 110 and the return well 112 may each be vertical, horizontal, comprise any angled deviation, and any combination thereof.

In certain embodiments, each of the supply well 110 and the return well 112 may comprise a casing 124a and 124b, respectively (collectively referred to herein as “the casing 124”). The casing 124 of each one of the supply well 110 and the return well 112 may be disposed along the circumference within the interior of the supply well 110 or the return well 112. The casing 124 may be any suitable tubular structure disposed to maintain the structural integrity of at least a portion of the supply well 110 and the return well 112. For example, a length of the casing 124 may be less than a length of the supply well 110 or the return well 112, wherein the lower portion unprotected by the casing 124 may be an open borehole. In embodiments, the length of the casing 124 may be approximately equivalent to the length of the supply well 110 or the return well 112. Each of the supply well 110 and the return well 112 may further comprise a wellhead 126a and 126b, respectively (collectively referred to herein as “the wellhead 126”). The wellhead 126 of each one of the supply well 110 and the return well 112 may be disposed at a top of the casing 124 and operable to seal the supply well 110 or the return well 112. In embodiments, there may be any other suitable equipment, components, piping, and the like operable to fluidly couple the supply well 110 and the return well 112 to the geothermal cooling loop 102. In one or more embodiments, there may be a plurality of supply wells 110 and/or a plurality of return wells 112 within the geothermal system 100, wherein one of ordinary skill in the art would recognize that functions and operability of a singular supply well 110 or return well 112 may be applied to the plurality of supply wells 110 and the plurality of return wells 112. Without limitations, the number of the plurality of supply wells 110 may be selected from a range of from about 2 to about 64, and the number of the plurality of return wells 112 may be selected from a range of from about 2 to about 32. For example, there may be at least about 5, 10, or 15 supply wells 110 and/or about 4, 8, or 12 return wells 112.

As shown in FIG. 1, the heat exchanger 114 may be disposed along the geothermal cooling loop 102 between the data center 106 and the aquifer 104. In some embodiments, the heat exchanger 114 may be separate from the geothermal cooling loop 102. The heat exchanger 114 may be operable to transfer heat from the intermediate fluid 132 to the geothermal fluid 108 prior to injection of the geothermal fluid 108 into the aquifer 104 through the supply well 110. Any suitable heat exchanger, or collection of equipment operable to remove heat, may be utilized as the heat exchanger 114. Without limitations, the heat exchanger 114 may be a shell and tube heat exchanger, plate heat exchanger, plate and shell heat exchanger, plate fin heat exchanger, adiabatic wheel heat exchanger, finned tube heat exchanger, microchannel heat exchanger, and the like. In some embodiments, the heat exchanger 114 may be a liquid-to-liquid heat exchanger. The heat exchanger 114 may employ parallel-flow, counter-flow, cross-flow, and any combination thereof. As illustrated, the supply well 110 and the return well 112 may be in fluid communication with the heat exchanger 114.

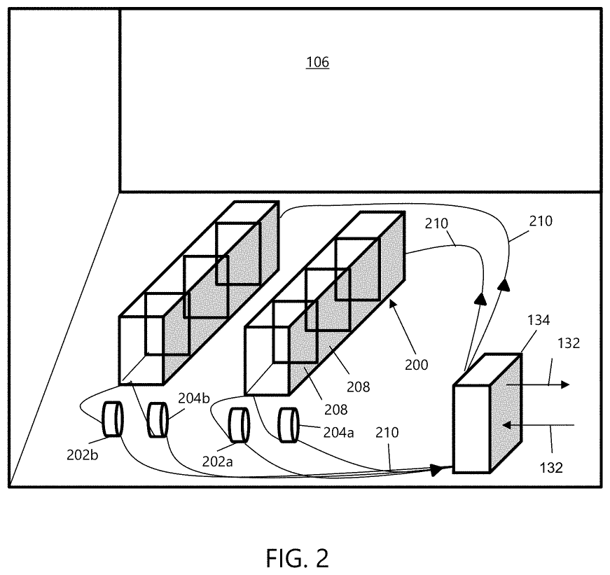

During operations, the heat exchanger 114 may receive the intermediate fluid 132 from a coolant distribution unit 134. The coolant distribution unit 134 may be configured to transfer heat from the heat transfer fluid 210 to the intermediate fluid 132. Similar to the heat exchanger 114, the coolant distribution unit 134 may be any suitable heat exchanger or collection of equipment operable to transfer heat between fluids. As shown in FIG. 1, the coolant distribution unit 134 may be disposed external to the data center 106. In some embodiments, the coolant distribution unit 134 may be disposed within the data center 106 (as seen in FIG. 2). The coolant distribution unit 134 may be configured to receive the heat transfer fluid 210 from the data center 106 (e.g., from one or more server racks) at a first temperature and to receive the intermediate fluid 132. The coolant distribution unit 134 may then transfer heat from the heat transfer fluid 210 to the intermediate fluid 132. The heat transfer fluid 210 may be discharged from the coolant distribution unit 134 at a second temperature, wherein the second temperature is less than the first temperature. Further, the intermediate fluid 132 may be discharged from the coolant distribution unit 134 at a third temperature.

The heat exchanger 114 may receive the intermediate fluid 132 discharged by the coolant distribution unit 134 at the third temperature and receive the geothermal fluid 108 produced by the return well 112. The heat exchanger 114 may be operable to transfer heat from the intermediate fluid 132 to the geothermal fluid 108 produced by the return well 112. The intermediate fluid 132 may be discharged from the heat exchanger 114 at a fourth temperature, and the geothermal fluid 108 produced by the return well 112 may be discharged from the heat exchanger 114 at a fifth temperature. In embodiments, the third temperature may be greater than the fourth temperature, such that the intermediate fluid 132 exits the heat exchanger 114 at a lower temperature. The geothermal fluid 108 may exit the heat exchanger 114 at the fifth temperature and enter the heat exchanger 114 from the return well 112 at a sixth temperature. The sixth temperature may be less than the fifth temperature, such that the geothermal fluid 108 receives heat from the intermediate fluid 132 when passing through the heat exchanger 114. For example, the third temperature, fourth temperature, sixth temperature, and fifth temperature may be about 80° F., about 62° F., 55° F., and 77° F., respectively.

The geothermal cooling loop 102 comprises the one or more system pumps 116 and the one or more temperature sensors 118 disposed at various locations along the geothermal cooling loop 102. The one or more system pumps 116 may be disposed between the data center 106 and the aquifer 104 and operable to maintain a fluid flow of the geothermal fluid 108, intermediate fluid 132, and/or heat transfer fluid 210. For example, a system pump 116a may be disposed between the return well 112 and the heat exchanger 114, and a system pump 116b may be disposed between the heat exchanger 114 and the supply well 110. The geothermal system 100 is not limited to such a number of one or more system pumps 116 or their respective locations. For example, the geothermal system 100 could include additional pumps positioned between the heat exchanger 114 and the coolant distribution unit 134. Each of the one or more system pumps 116 may be any suitable pump or device operable to facilitate fluid flow. In embodiments, the one or more system pumps 116 may each be a variable speed pump. In one or more embodiments, the one or more system pumps 116 may be actuated to vary a flow rate of the geothermal fluid 108, intermediate fluid 132, and/or heat transfer fluid 210 based on temperature measurements received by the one or more temperature sensors 118.

The one or more temperature sensors 118 may also be disposed between the data center 106 and the aquifer 104 and operable to measure a temperature of the geothermal fluid 108, intermediate fluid 132, and/or the heat transfer fluid 210. For example, the one or more temperature sensors 118 may be disposed in proximity to the heat exchanger 114. For example, temperature sensor 118a may be disposed between the coolant distribution unit 134 and a heat transfer fluid inlet 130a of the heat exchanger 114 operable to measure the third temperature of the intermediate fluid 132. Temperature sensor 118b may be disposed between the return well 112 and a geothermal fluid inlet 130b of the heat exchanger 114 operable to measure the sixth temperature of the geothermal fluid 108. Temperature sensor 118c may be disposed between the supply well 110 and a geothermal fluid outlet 130c of the heat exchanger 114 operable to measure the fifth temperature of the geothermal fluid 108. Temperature sensor 118d may be disposed between the coolant distribution unit 134 and a heat transfer fluid outlet 130d of the heat exchanger 114 operable to measure the fourth temperature of the intermediate fluid 132. The geothermal system 100 is not limited to such a number of one or more temperature sensors 118 or their respective locations.

In some embodiments, the geothermal loop 102 may include a secondary heat exchanger 128 to at least partially cool the intermediate fluid 132 prior to entering the heat exchanger 114. Secondary heat exchanger 128 may be any suitable heat exchange device such as a cooler, liquid-to-liquid heat exchanger, air-liquid heat exchanger, heat pump, other thermal dissipation devices, or any combination thereof. In some embodiments, one or more additional heat exchangers or heat pumps could be located at various points of the process where additional heat transfer is desirable.

FIG. 2 is a partial isometric view of an example data center 106, according to one or more embodiments. The data center 106 may be any suitable enclosure or building operable to house and operate storage systems. In embodiments, the data center 106 may be a hyperscale data center operable to consume at least 10 megawatts, at least 20 megawatts, or at least 30 megawatts of electricity during operations. In some embodiments, the data center 106 may be a 30-megawatt data center comprising three 10-megawatt data halls. As illustrated, the data center 106 may include one or more server racks 200, a first pump 202, a second pump 204, and the coolant distribution unit 134. Whereas FIG. 1 depicts coolant distribution unit 134 outside and separate from the data center 106, FIG. 2 depicts an embodiment of the coolant distribution unit 134 in which it is located inside the data center 106. The one or more server racks 200 may be operable to structurally support one or more server 208 of the data center 106. Each of the one or more server racks 200 may be any suitable size, height, shape, or combination thereof. Each of the one or more server racks 200 may comprise any suitable material operable to support the one or more servers 208, such as metals, nonmetals, composites, polymers, rubbers, and any combination thereof.

The one or more servers 208 may be any suitable computing systems operable to perform functions or store information. Each of the one or more servers 208 may comprise any suitable hardware, such as processors, memories, network interfaces, and the like. In embodiments, the one or more servers 208 may be in thermal communication with a heat transfer fluid 210. For example, in certain embodiments, at least a portion of the one or more servers 208 may be immersed in the heat transfer fluid 210. In other embodiments, at least one or all of the one or more servers may be immersed in the heat transfer fluid 210. The heat transfer fluid 210 may be any suitable thermally conductive fluid (e.g., a coolant). During operations, the one or more servers 208 may generate waste heat. The heat transfer fluid 210 may be operable to absorb the produced waste heat and transfer the waste heat to the intermediate fluid 132 for subsequent transfer to the geothermal fluid 108 (referring to FIG. 1) of the geothermal cooling loop 102 (referring to FIG. 1) to be rejected into the aquifer 104 (referring to FIG. 1).

As illustrated, each of the one or more server racks 200 may be fluidly coupled to a respective first pump 202 and second pump 204. In embodiments, each one of the first pump 202 and the second pump 204 may be configured to maintain a fluid flow of the heat transfer fluid 210 to the coolant distribution unit 134. The first pump 202 may initially be activated and operating during operations of the server rack 200. The second pump 204 may be configured to activate in response to at least a partial failure of the first pump 202. Each of the first pump 202 and second pump 204 may be any suitable pump or device operable to facilitate fluid flow. In embodiments, the first pump 202 and second pump 204 (or any other pump in the geothermal system) may be a variable speed pump. In one or more embodiments, the first pump 202 or second pump 204 may be actuated to vary a flow rate of the heat transfer fluid 210 based on temperature measurements received by the one or more temperature sensors 118 (referring to FIG. 1). For example, the flow rate of the heat transfer fluid 210 may be at least partially maintained based on the temperature of the geothermal fluid 108 at a location along the geothermal cooling loop 102 (referring to FIG. 1). In another example, one or more temperature sensors 118 (not shown) may be disposed about the data center 106 and operable to measure a temperature of the heat transfer fluid 210, the server racks 200, and/or the servers 208. In this example, the flow rate of the heat transfer fluid 210 may be at least partially maintained based on the temperature of the heat transfer fluid 210 throughout the data center 106.

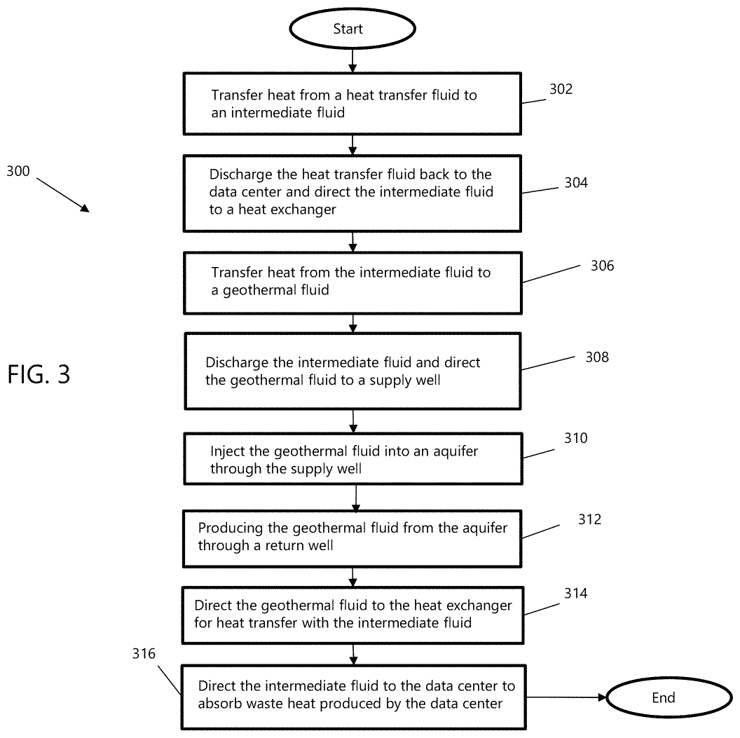

FIG. 3 is a flowchart of an example method 300 using the geothermal system 100 of FIG. 1, according to one or more aspects of the present disclosure. At step 302, the first pump 202 (referring to FIG. 2) or second pump 204 (referring to FIG. 2) may direct a flow of the heat transfer fluid 210 (referring to FIG. 2) from the one or more server racks 200 (referring to FIG. 2) to the coolant distribution unit 134 (referring to FIG. 2). In embodiments, the coolant distribution unit 134 may be located within the data center 106 (referring to FIG. 2) or disposed along the geothermal cooling loop 102 (referring to FIG. 1). In these embodiments, the heat transfer fluid 210 may be carrying waste heat produced by the data center 106 to be transferred to the intermediate fluid 132 (referring to FIG. 1) for subsequent transfer to the geothermal cooling loop 102 for transfer to the earth's crust via the aquifer 104 (referring to FIG. 1). The coolant distribution unit 134 may receive the heat transfer fluid 210 from the data center 106 at a first temperature and receive the intermediate fluid 132. The coolant distribution unit 134 may then facilitate the transfer of heat from the heat transfer fluid 210 to the intermediate fluid 132.

At step 304, the coolant distribution unit 134 may discharge the cooled heat transfer fluid 210 back to the one or more server racks 200 of the data center 106 at a second temperature. The coolant distribution unit 134 may further discharge the intermediate fluid 132 at a higher temperature and direct the heated intermediate fluid 132 towards the heat exchanger 114 (referring to FIG. 1). Prior to the heat exchanger 114 receiving the intermediate fluid 132, the secondary heat exchanger 128 (referring to FIG. 1) may reduce the temperature of the intermediate fluid 132 by removing heat from the discharged flow of intermediate fluid 132 from the coolant distribution unit 134.

At step 306, the heat exchanger 114 may receive a flow of the geothermal fluid 108 (referring to FIG. 1) from the geothermal cooling loop 102 and may receive the intermediate fluid 132. The heat exchanger 114 may facilitate heat transfer from the intermediate fluid 132 to the geothermal fluid 108, wherein the temperature of the geothermal fluid 108 increases and the temperature of the intermediate fluid 132 decreases.

At step 308, the heat exchanger 114 may discharge the cooled intermediate fluid 132 back to the coolant distribution unit 134. The heat exchanger 114 may further discharge the geothermal fluid 108 at a higher temperature and direct the heated geothermal fluid 108 towards the supply well 110 (referring to FIG. 1).

At step 310, the geothermal fluid 108 may be injected into the aquifer 104 through the supply well 110. In certain embodiments, there may be a plurality of supply wells 110, wherein the geothermal fluid 108 may be injected through each one of the plurality of supply wells 110. At step 312, the geothermal fluid 108 may be produced from the aquifer 104 through the return well 112 (referring to FIG. 1) at a lower temperature. In one or more embodiments, there may be a plurality of return wells 112, wherein the geothermal fluid 108 may be produced through each one of the plurality of return wells 112.

At step 314, the geothermal fluid 108 may be directed from the return well 112 to the heat exchanger 114. The geothermal fluid 108 may be received by the heat exchanger 114 for facilitation of heat transfer with the intermediate fluid 132. At step 316, the intermediate fluid 132 may be directed to the coolant distribution unit 134 after transferring heat to the geothermal fluid 108. The intermediate fluid 132 may absorb heat from the heat transfer fluid 210 circulating through the coolant distribution unit 134. The heat transfer fluid 210 may then be received by the one or more server racks 200 at a cooler temperature after flowing through the coolant distribution unit 134. The heat transfer fluid 210 may then be used to absorb heat produced through operation of the one or more server racks 200 and be discharged to cycle back to the coolant distribution unit 134, wherein the intermediate fluid 132 may absorb that heat from the heat transfer fluid 210. The method 300 may proceed back to step 302 and repeat a suitable number of times or may proceed to end.

Therefore, the disclosed systems and methods are well adapted to attain the ends and advantages mentioned as well as those that are inherent therein. The particular embodiments disclosed above are illustrative only, as the teachings of the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope of the present disclosure. The systems and methods illustratively disclosed herein may suitably be practiced in the absence of any element that is not specifically disclosed herein and any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. A system using geothermal cooling for data centers, comprising:
a data center comprising one or more server racks in thermal communication with a heat transfer fluid, wherein each of the one or more server racks comprises one or more servers;
a coolant distribution unit configured to:
receive the heat transfer fluid from the one or more server racks at a first temperature;
transfer heat from the heat transfer fluid to an intermediate fluid;
discharge the heat transfer fluid at a second temperature, wherein the second temperature is less than the first temperature; and
discharge the intermediate fluid at a third temperature; and
a geothermal cooling loop, comprising:
a first heat exchanger configured to:
receive the intermediate fluid from the coolant distribution unit;
transfer heat from the intermediate fluid to a geothermal fluid;
discharge the intermediate fluid at a fourth temperature, wherein the fourth temperature is less than the third temperature; and
discharge the geothermal fluid at a fifth temperature;
at least one supply well penetrating at least a first portion of an aquifer and operable to receive the discharged geothermal fluid from the first heat exchanger, wherein the discharged geothermal fluid is introduced into the aquifer via the at least one supply well; and
at least one return well penetrating at least a second portion of the aquifer and operable to produce at least a portion of the geothermal fluid from the aquifer at a sixth temperature, wherein the sixth temperature is less than the fifth temperature;
wherein the at least one return well is in fluid communication with the first heat exchanger.

2. The system of claim 1, wherein the one or more server racks are operable to consume at least 10 megawatt hours of electricity.

3. The system of claim 1, further comprising a secondary heat exchanger operable to reduce a temperature of the intermediate fluid before the intermediate fluid is directed to the first heat exchanger.

4. The system of claim 1, further comprising:
a first pump associated with each one of the one or more server racks; and
a second pump associated with each one of the one or more server racks, wherein each one of the first pump and the second pump is configured to maintain a fluid flow of the heat transfer fluid to the coolant distribution unit.

5. The system of claim 4, wherein the second pump is configured to activate in response to at least a partial failure of the first pump.

6. The system of claim 4, further comprising one or more temperature sensors disposed between the data center, the first heat exchanger, and the aquifer.

7. The system of claim 6, wherein at least one of the first pump and the second pump is a variable speed pump and is actuated to vary a flow rate of the heat transfer fluid based, at least in part, on temperature measurements received by the one or more temperature sensors.

8. The system of claim 1, further comprising one or more system pumps disposed between the data center and the aquifer operable to maintain a fluid flow of the geothermal fluid.

9. The system of claim 1, wherein at least a portion of the one or more servers are immersed in the heat transfer fluid.

10. The system of claim 1, wherein each one of the at least one supply well and the at least one return well comprises:
a casing disposed along the circumference of at least a portion of the supply well or the return well; and
a wellhead disposed at a top of the casing operable to seal the supply well or the return well.

11. The system of claim 1, further comprising a plurality of supply wells or a plurality of return wells.

12. A method of rejecting heat from data centers through geothermal cooling, comprising:
using a coolant distribution unit to transfer heat from a heat transfer fluid received from a data center comprising one or more server racks at a first temperature to an intermediate fluid, wherein each of the one or more server racks comprises one or more servers;
discharging the heat transfer fluid from the coolant distribution unit to the data center at a second temperature, wherein the second temperature is less than the first temperature;
discharging the intermediate fluid from the coolant distribution unit at a third temperature;
using a first heat exchanger to transfer heat from the intermediate fluid received from the coolant distribution unit to a geothermal fluid received from a geothermal cooling loop;
discharging the intermediate fluid at a fourth temperature and the geothermal fluid at a fifth temperature;
directing the discharged geothermal fluid to at least one supply well penetrating at least a first portion of an aquifer;
injecting the geothermal fluid into the aquifer through the at least one supply well;
producing the geothermal fluid from the aquifer at a sixth temperature through at least one return well penetrating at least a second portion of the aquifer, wherein the sixth temperature is less than the fifth temperature; and
directing the produced geothermal fluid to the first heat exchanger for heat transfer between the produced geothermal fluid and the intermediate fluid.

13. The method of claim 12, further comprising consuming at least 10 megawatts of electricity during operation of the data center.

14. The method of claim 12, further comprising operating a first pump associated with each one of the one or more server racks.

15. The method of claim 14, further comprising activating a second pump associated with each one of the one or more server racks in response to at least a partial failure of the first pump.

16. The method of claim 12, further comprising measuring a temperature of the geothermal fluid with one or more temperature sensors disposed between the data center and the aquifer.

17. The method of claim 16, further comprising varying a flow rate of the geothermal fluid based, at least in part, on temperature measurements received by the one or more temperature sensors.

18. The method of claim 12, further comprising actuating one or more system pumps disposed between the data center and the aquifer to maintain a fluid flow of the geothermal fluid.

19. The method of claim 12, wherein at least a portion of the one or more servers are immersed in the heat transfer fluid.

20. The method of claim 12, further comprising:
injecting the geothermal fluid into the aquifer through a plurality of supply wells; and
producing the geothermal fluid from the aquifer through a plurality of return wells.
